(19) United States
(12) Patent Application Publication
(10) Pub. No.: US 2011/0012019 A1
(43) Pub. Date: Jan. 20, 2011

(54) MIRROR SWITCH APPARATUS

(76) Inventor: LAN-RONG DUNG, Hsinchu (TW)

Correspondence Address: STOUT, UXA, BUYAN & MULLINS LLP, 4 VENTURE, SUITE 300, IRVINE, CA, 92618, US

(21) Appl. No.: 12/502,832

(22) Filed: Jul. 14, 2009

(51) Int. Cl. G01J 5/02; H03K 17/78

(52) U.S. Cl. 250/353; 250/214 SW

(57) ABSTRACT

A mirror switch apparatus for controlling an electronic device includes a directional light source generator, a mirror component, and a light receiver. The directional light source generator is used to provide a directional light to be transmitted to the mirror component. The light receiver is used to control the electronic device. When the light receiver receives the directional light reflected from the mirror component the mirror switch apparatus is activated to control the electronic device, such as by turning the device on/off.

### BACKGROUND OF THE INVENTION

1. Field of the Invention

The present invention relates to a mirror switch apparatus, and more particularly to a mirror switch apparatus that is activated to control an electronic device, such as by turning it on/off or dimming it high/low, by way of a light reflective theorem.

2. Description of the Prior Art

Most embodiments of conventional switch apparatuses, which are operable for controlling electronic devices, are wired switch apparatuses installed at an immovable location (such as a wall or a cabinet) and electrically connected to and for control of the electronic device (such as a lamp, and so on). Those wired switch apparatuses are installed when the house is in construction or in remodeling. If one wishes to relocate the switch apparatus, the switch apparatus needs to be removed from the fixed location, and the electrical wire also needs to be reset to a new location. The installation steps of the wired switch apparatus are cumbersome and complicated, and sometimes the wired switch apparatus can only be removed by digging into the wall. It is very inconvenient. In addition, if the wire of the switch apparatus is not hidden in the wall or cabinet, the sight of the wire, exposed, is not pleasing to the eye.

In addition to the mentioned switch apparatuses, there are also wireless control switch apparatuses in the market. For example, infrared remote control switches and radio frequency (RF) remote control switches have each gained popularity as wireless control switch apparatuses. The infrared remote control switch causes an electronic device to turn on/off by way of an infrared flicker frequency, and the RF remote control switch activates the turn on/off control function by way of a radio frequency signal. However, wireless remote control switch apparatuses are driven by electrical power thus requiring frequent changing of batteries, and each of the electronic devices generally has to “come with” a remote switch apparatus. Also, as there are so many different remote switch apparatuses in a typical user's life, it is increasingly hard to find the right switch apparatus when it is needed. Sound remote control switches, while also belonging to the family of wireless control switch apparatuses, have sound signals that are easily interrupted by environmental noise, presenting low sound identification problems.

Therefore, a need exists to design a switch apparatus that is not difficult to install, that can easily be relocated, and that requires little to no power.

### SUMMARY OF THE INVENTION

The main object of the present invention is to provide a mirror switch apparatus used to overcome the immovability drawback of the conventional switch apparatus.

The other object of the present invention is to provide a mirror switch apparatus the location of which can easily be changed by a user without affecting the switching function.

According to the objects described above, a mirror switch apparatus is provided herein and includes a directional light source generator, a mirror component, and a light receiver. The directional light source generator is used to provide a directional light. The directional light is transmitted to the mirror component. The light receiver is used to receive the directional light reflected from the mirror component so as to activate the mirror switch apparatus to turn on/off.

According to the objects described above, a mirror switch apparatus includes a directional light source generator, a rotatable mirror component, and a light receiver. The directional light source generator is used to provide a directional light. The directional light is transmitted to the rotatable mirror component. The light receiver is used to receive the directional light reflected from the mirror component so as to activate the mirror switch apparatus to turn on/off. The mirror switch apparatus rotates the rotatable mirror component to avoid the directional light reflected to the light receiver so as to turn on/off the mirror switch apparatus.

According to the objects described above, a mirror switch apparatus includes a directional light source generator, a mirror component, and a light receiver. The directional light source generator is used to provide a directional light. The mirror component includes a mirror (or reflective) surface and a non-mirror (or nonreflective) surface, and the directional light is transmitted to the mirror component. The light receiver is used to receive the directional light reflected from the mirror component so as to activate the mirror switch apparatus to turn on/off. The mirror surface of the mirror component is faced to the directional light source generator, and the directional light is reflected to the light receiver; the non-mirror surface of the mirror component is faced to the directional light source, and the directional light is not reflected to the light receiver so as to activate the mirror switch apparatus to turn on/off.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A and FIG. 1B are views illustrating a first embodiment of the mirror switch apparatus of the present invention;

FIG. 2A and FIG. 2B are views illustrating a second embodiment of the mirror switch apparatus of the present invention;

FIG. 3A, FIG. 3B and FIG. 3C are views illustrating a third embodiment of the mirror switch apparatus of the present invention; and

FIG. 4A, FIG. 4B and FIG. 4C are views showing a fourth embodiment of the mirror switch apparatus of the present invention.

### DESCRIPTION OF THE PREFERRED EMBODIMENTS

The detailed description of the present invention will be discussed in the following embodiments, which are not intended to limit the scope of the present invention and which can be adapted for other applications. While the drawings are illustrated in detail, it is appreciated that the quantity of the disclosed components may be greater or less than that disclosed, except for instances expressly restricting the amount of the components.

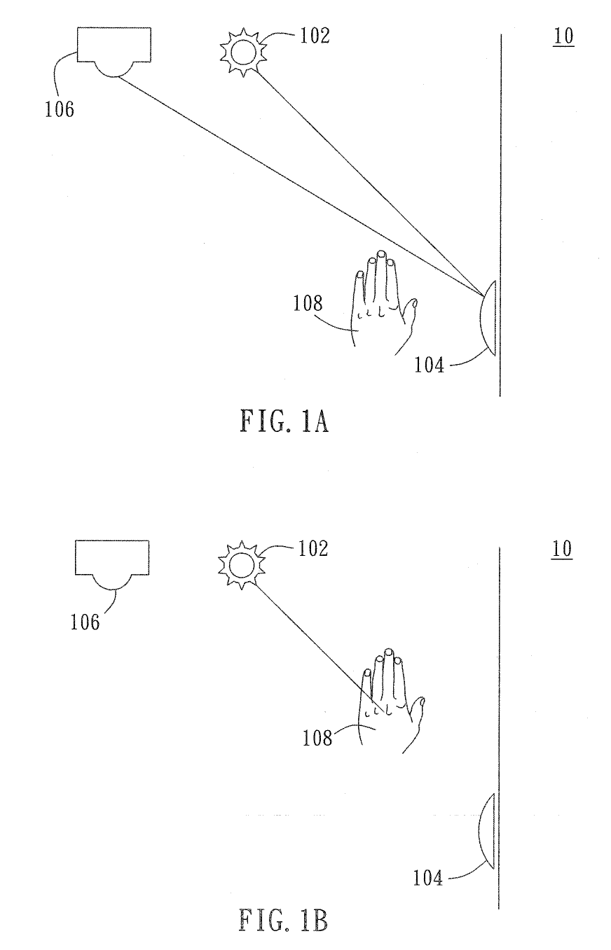

FIG. 1A and FIG. 1B are views illustrating a first embodiment of the mirror switch apparatus of the present invention. As shown in FIG. 1A, the mirror switch apparatus 10 includes a directional light source generator 102, a mirror component 104 and a light receiver 106. The directional light source generator 102 is a device used to provide a directional light and the directional light is transmitted to the mirror component 104. The light generated by the directional light source generator 102 is a visible light (such as laser light, and so on) or an invisible light (such as infrared ray light, and so on). The mirror component 104 can be a mirror or any other component(s) with the light reflective function of a mirror or mirror-like surface. In the present embodiment, the mirror component 104 is fixed or adhered to an immovable location (such as a wall or the surface of an item of furniture). The light receiver 106 is used to receive light reflected from the mirror component 104. When light reflected from the mirror component 104 is blocked by an object 108 (such as a human hand), as shown in FIG. 1B, the light receiver 106 is not able to detect the light reflected from the mirror component 104, in which case the mirror switch apparatus 10 then controls (e.g., activates the switching of) the electronic device. For example, when the mirror switch apparatus 10 is activated to turn on/off the electronic device, it is determined according to how many times the light receiver 106 cannot detect the light in a specific time interval. For instance, when a user waves his hand to block the mirror component 104 twice in one second, the mirror switch apparatus 10 will be activated to perform the switching operation. In a different embodiment, the switching operation is determined by the length of the time that the light receiver 106 is unable to detect the light. For example, when the user waves his hand to block the mirror component 104 and stops there for about 0.5 to 1 second, the mirror switch apparatus 10 will activate the switching operation. It should be noted that the examples described above are used to explain how the mirror switch apparatus 10 of the present invention can activate the switching operation, and thus no limitation should be implied that the mirror switch apparatus 10 of the present invention only can activate the switching operation by these two examples.

Furthermore, it should be noted that the mirror switch apparatus 10 in a different embodiment is not only used in turning on/off the electronic device, but it is also used to adjust the energy intensity of the electronic device, such as by adjusting the volume of a television or the luminance of a lamp. According to the cover portion of the mirror component 104 blocked by the user, the light receiver 106 is able to increase or decrease the energy intensity of the electronic device by the reflective light power. In another example, according to the number of cover times to block the mirror component 104, the light receiver 106 will controllably adjust the energy intensity of the electronic device step by step. For instance, when the lamp is off, the user blocks the mirror component 104 once and the lamp will turn on. When the user blocks the mirror component 104 again, the luminance intensity of the lamp is increased, and so on. When the user blocks the mirror component 104 a last time, the lamp will be turned off. Again, it should be noted that the examples described above are used to explain how the mirror switch apparatus 10 of the present invention can adjust the energy intensity of the electronic device, and are not intended to limit operation of the mirror switch apparatus 10 of the present invention to only being able to adjust the energy intensity of the electronic device by these two examples.

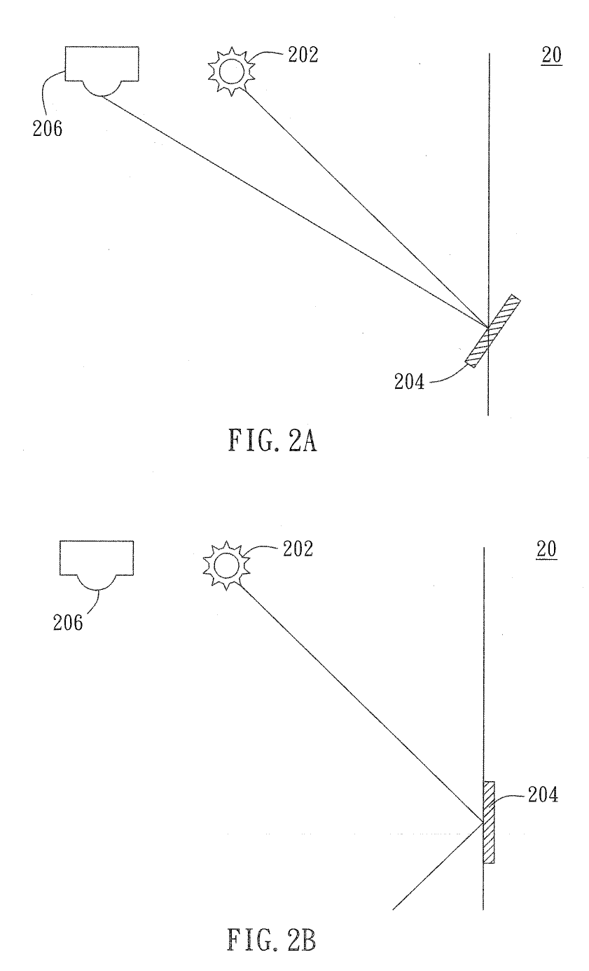

FIG. 2A and FIG. 2B are views showing a second embodiment of the mirror switch apparatus of the present invention. As shown in FIG. 2A, the mirror switch apparatus 20 also includes a directional light source generator 202, a mirror component 204, and a light receiver 206. Compared to the mirror switch apparatus 10 of the first embodiment, the mirror component 204 of the mirror switch apparatus 20 is a rotatable mirror component 204. By rotating the mirror component 204, the light receiver 206 is not able to receive the reflective light from the mirror component 204. In other words, the light receiver 206 is enabled to detect the light by changing the reflective angle of the mirror component 204. For example, when the reflective surface of the mirror component 204 reflects the light to an area outside of the detective range of the light receiver 206, as shown in FIG. 2B, the light receiver 206 cannot detect the light signal so as to active the switching operation of the electronic device. And then, in an example, the mirror component 204 can be rotated more or will keep rotating. When the mirror component 204 is rotated back into the detecting range of the light receiver 206, the mirror switch apparatus 20 will activate the switching operation of the electronic device again.

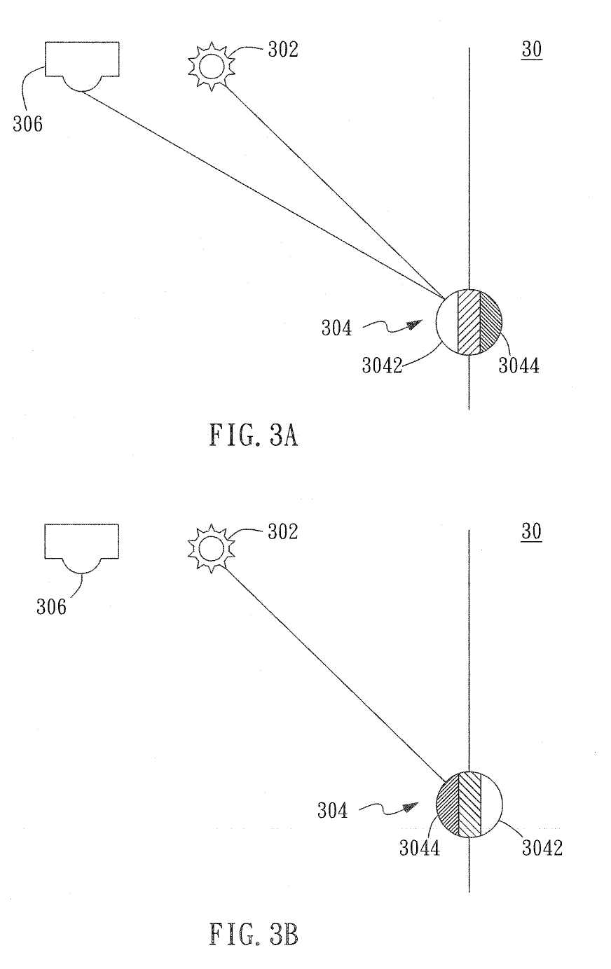

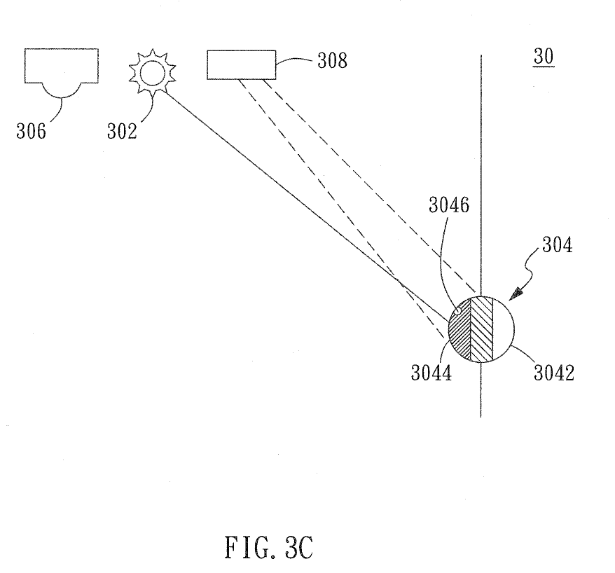

FIG. 3A, FIG. 3B and FIG. 3C are views showing a third embodiment of the mirror switch apparatus of the present invention. As shown in FIG. 3A, the mirror switch apparatus 30 of the third embodiment also includes a directional light source generator 302, a mirror component 304, and a light receiver 306. Comparing the present embodiment with the embodiments described above, the mirror switch apparatus 30 operates to change the light detective state by changing the mirror surface and a non-mirror surface. Therefore, there are a mirror surface 3042 and a non-mirror surface 3044 included in the mirror component 304. When the user rotates the non-mirror surface 3044 of the mirror component 304 to face toward the directional light source generator 302, the light receiver 306 is not able to detect the reflective light, as shown in FIG. 3B, so as to activate the switching operation of the electronic device. For example, when the non-mirror surface 3044 is pointed into the directional light source generator 302, the electronic device is off. When the mirror surface 3042 is faced to the directional light source generator 302, the electronic device is turned on. A different embodiment can be implemented to avoid erroneous interpretation, by the mirror switch apparatus, of accidental blocking of the mirror surface as an instruction to turn off the electronic device. Here, there is an image sensor 308 in the mirror switch apparatus 30, as shown in FIG. 3C. The surface of the non-mirror surface 3044 further includes a specific mark 3046. By utilizing the image sensor 308 of the present invention, it is able to detect the mark 3046 on the non-mirror surface 3044 to confirm the activation of the switching operation of the electronic device.

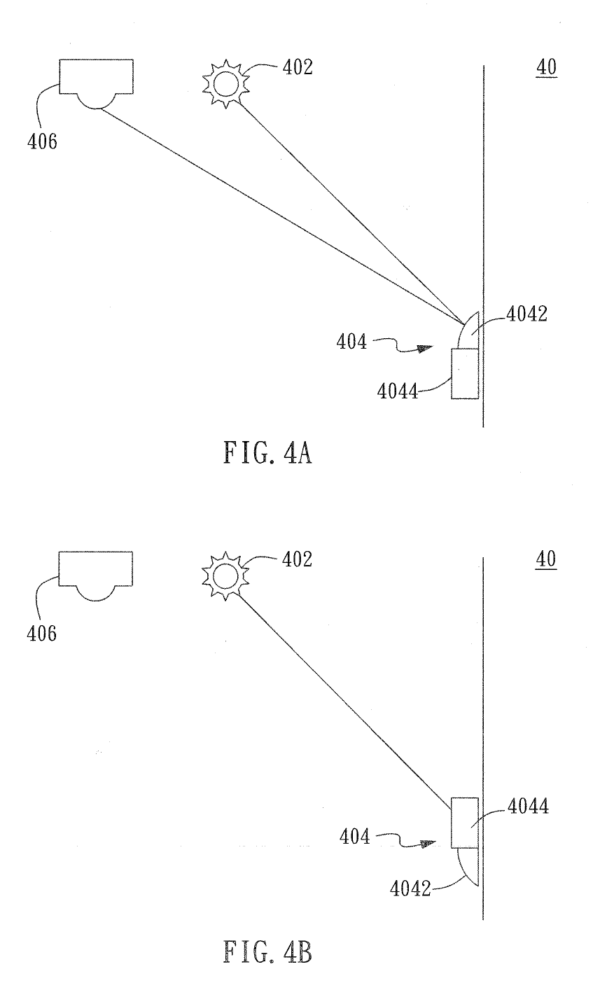

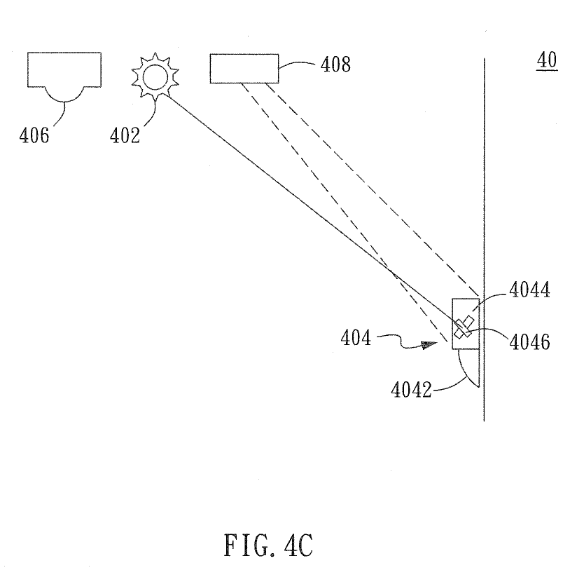

FIG. 4A, FIG. 4B and FIG. 4C are views showing a fourth embodiment of the mirror switch apparatus of the present invention. As shown in FIG. 4A, the mirror switch apparatus 40 of the fourth embodiment includes a directional light source generator 402, a mirror component 404 and a light receiver 406. The mirror surface and the non-mirror surface are also implemented in the fourth embodiment. The mirror component 404 includes a mirror surface 4042 and a non-mirror surface 4044. Comparing to the third embodiment, the mirror component 404 of the fourth embodiment is a sliding mirror component 404. The mirror surface 4042 of the mirror component 404 is faced to the directional light source generator 402, and the light receiver 406 will receive the reflective light from the mirror component 404. When the non-mirror surface 4044 is slid up, as shown in FIG. 4B, the non-mirror surface 4044 blocks the light transmitted on the mirror component 404. Therefore, the light receiver 406 is not able to detect the reflective light from the mirror component 404, and the switching operation of the electronic device is activated.

Because there is no power element included in the mirror component of the mirror switch apparatus of the present invention, and it may be difficult to locate the mirror switch apparatus in a dark room, a fluorescent agent (such as a fluorescent agent for infrared rays) can be applied near the mirror component in a different embodiment. The invisible light generated by the directional light source generator will induce the fluorescent agent whereby the user is able to identify the location of the mirror switch apparatus. In addition, in order to save energy consumption of the directional light source generator, an infrared ray sensor can be used in the present invention. When a user is in the detectable range of the mirror switch apparatus, the infrared ray sensor will detect the variation of the infrared spectrogram of the human body so as to turn on the directional light source generator. When the user stays in one place for a predetermined (e.g., long) period of time or the user is out of the detective range of the mirror switch apparatus, the directional light source generator will automatically turn off at a specific time.

Although specific embodiments have been illustrated and described, it will be appreciated by those skilled in the art that various modifications may be made without departing from the scope of the present invention, which is intended to be limited solely by the appended claims.

What is claimed is:

1. A mirror switch apparatus, comprising:
a directional light source generator used to provide a directional light;
a mirror component whereby said directional light is aligned to be transmitted to said mirror component; and
a light receiver used to receive said directional light reflected from said mirror component so as to activate said mirror switch apparatus to turn on/off or enable one or more control operations.

2. The mirror switch apparatus according to claim 1, wherein said mirror switch apparatus is activated by blocking said mirror component causing said directional light reflected from said mirror component not to be received by said light receiver.

3. The mirror switch apparatus according to claim 1, wherein said mirror component is a rotatable mirror component.

4. The mirror switch apparatus according to claim 3, wherein said rotatable mirror component is rotated to force the directional light not to be transmitted to said light receiver so as to activate said mirror switch apparatus.

5. The mirror switch apparatus according to claim 1, wherein said mirror component further includes a mirror surface and a non-mirror surface.

6. The mirror switch apparatus according to claim 5, wherein facing of said mirror surface of said mirror component toward said directional light source generator causes said directional light to be reflected to said light receiver, and facing of said non-mirror surface of said mirror component toward said directional light source generator causes said directional light not to be reflected to said light receiver so as to activate said mirror switch apparatus.

7. The mirror switch apparatus according to claim 6, further including an image sensor and a mark applied on said non-mirror surface, and said image sensor being configured to detect said mark to confirm that said non-mirror surface is faced to said directional light source generator and that said mirror switch apparatus is to be activated.

8. The mirror switch apparatus according to claim 5, wherein said non-mirror component is a sliding non-mirror component, and said non-mirror component is configured to be slid to block said mirror surface whereby said directional light is not reflected to said light receiver so as to activate said mirror switch apparatus.

9. The mirror switch apparatus according to claim 1, further including an infrared ray sensor, said infrared ray sensor being configured to detect an infrared spectrogram of a human body to turn on said directional light source generator.

10. The mirror switch apparatus according to claim 1, further including a fluorescent agent, said fluorescent agent being induced by said directional light of said directional light source generator whereby the location of said mirror switch apparatus can be easily identified by a user.

11. The mirror switch apparatus according to claim 1, wherein said directional light is visible light.

12. The mirror switch apparatus according to claim 1, wherein said directional light is invisible light.

13. The mirror switch apparatus according to claim 12, wherein said invisible light is infrared light.

14. The mirror switch apparatus according to claim 1, wherein said mirror switch apparatus is further used to adjust an energy intensity of an electronic device.

15. A mirror switch apparatus, comprising:
a directional light source generator used to provide a directional light;
a rotatable mirror component whereby said directional light is provided by way of being transmitted to said rotatable mirror component; and
a light receiver used to receive said directional light reflected from said mirror component so as to activate said mirror switch apparatus to turn on/off;
wherein said mirror switch apparatus is configured such that rotation of said rotatable mirror component to cause said directional light not to be reflected to said light receiver causes a turn on/off action by said mirror switch apparatus.

16. The mirror switch apparatus according to claim 15, further including an infrared ray sensor, whereby said infrared ray sensor is configured to detect an infrared spectrogram of a human body to turn on said directional light source generator.

17. The mirror switch apparatus according to claim 15, further including a fluorescent agent, said fluorescent agent being induced by said directional light of said directional light source generator whereby the location of said mirror switch apparatus can be easily identified.

18. A mirror switch apparatus, comprising:
a directional light source generator configured to provide a directional light;
a mirror component including a mirror surface and a non-mirror surface whereby said directional light is transmitted to said mirror component; and
a light receiver configured to receive said directional light reflected from said mirror component so as to activate said mirror switch apparatus to turn on/off;
wherein when said mirror surface of said mirror component is faced to said directional light source generator said directional light is reflected to said light receiver, and when said non-mirror surface of said mirror component is faced to said directional light source said directional light is not reflected to said light receiver so as to turn on/off said mirror switch apparatus.

19. The mirror switch apparatus according to claim 18, further including an infrared ray sensor, said infrared ray sensor being configured to detect an infrared spectrogram of a human body to turn on said directional light source generator.

20. The mirror switch apparatus according to claim 18, further including a fluorescent agent, said fluorescent agent being induced by said directional light of said directional light source generator whereby the location of said mirror switch apparatus can easily be identified.
